(19) United States
(12) Patent Application Publication
(10) Pub. No.: US 2025/0223684 A1
(43) Pub. Date: Jul. 10, 2025

(54) Method for producing a coated object and coated object

(71) Applicant: Kennametal Inc., Latrobe, PA (US)

(72) Inventors: Joern Kohlscheen, Ebermannstadt (DE); Christian Bareiss, Ebermannstadt (DE)

(21) Appl. No.: 19/012,216

(22) Filed: Jan. 7, 2025

(30) Foreign Application Priority Data
Jan. 8, 2024 (DE) 1020241003421

(51) Int. Cl. C23C 14/06; C23C 14/35

(52) U.S. Cl. CPC C23C 14/0635; C23C 14/35

(57) ABSTRACT

A method for producing a coated object, wherein the method comprises the steps of: A substrate is provided in a reaction chamber and an anti-wear layer is deposited on a surface of the substrate by physical vapor deposition, wherein a target is provided in the reaction chamber, which target contains at least a first transition metal Ma that is a transition metal from the fifth or sixth group of the periodic table, in order to produce an Ma₂C phase in the anti-wear layer, and wherein the proportion of Ma of the Ma₂C phase in the anti-wear layer is at least 60 atomic percent, based on the total quantity of transition metals in the anti-wear layer. Furthermore, a coated object is indicated.

### RELATED APPLICATION DATA

The present application claims priority pursuant to 35 U.S.C. § 119 (a) to German Patent Application Number 1020241003421 filed Jan. 8, 2024 which is incorporated herein by reference in its entirety.

### FIELD

The invention relates to a method for producing a coated object and to a coated object.

### BACKGROUND

In order to increase the resistance of objects such as cutting and machining tools, it is common practice to apply coatings to the surface of the respective object, which are characterized in particular by a high degree of hardness. For example, coatings of titanium aluminum nitride (TiAlN), tungsten carbide (WC) or titanium carbide (TIC) can be deposited using physical vapor deposition (PVD). It is also known to apply amorphous carbon (also known as “diamond-like carbon”, DLC) as a coating of great hardness. However, such coatings are limited in terms of the achievable layer thickness and layer adhesion.

Coatings made of so-called “superhard” materials with a plastic hardness of more than 40 GPa are also known, for example, from titanium diboride (TiB₂). However, coatings made of superhard materials tend to be brittle, which has a negative impact on the lifespan of the coated objects they are applied to due to the tendency for them to chip off.

### SUMMARY

It is the object of the invention to provide a method for producing a coating that combines high hardness, low intrinsic voltage and good layer adhesion, and an object having such a coating.

The object is solved by a method for producing a coated object, wherein the method comprises the following steps:
providing a substrate in a reaction chamber, and
depositing an anti-wear layer on a surface of the substrate by means of physical vapor deposition, wherein a target containing at least a first transition metal Ma, which is a transition metal from the fifth or sixth group of the periodic table, is introduced into the reaction chamber to produce a Ma₂C phase in the anti-wear layer, and wherein the proportion of Ma of the Ma₂C phase in the anti-wear layer is at least 60 atomic percent, based on the total quantity of transition metals in the anti-wear layer.

The invention is based on the fundamental idea of applying an anti-wear layer that has a metal carbide phase with a high metal content, namely a dimetal carbide phase (Ma₂C phase), as its main component. It was found that such phases are characterized by a particularly high hardness and can be generated in a targeted manner by PVD methods by using a target in the reaction chamber as a cathode, which contains the respective transition metal Ma or consists of it and can thus release the transition metal Ma via the respective PVD method.

According to the invention, the use of metal monocarbide phases as the main component in the anti-wear layer, as produced by sintering and/or chemical vapor deposition (CVD) by equilibrium processes, for example TiC or WC, is dispensed with. This does not, of course, rule out the possibility that a small number of such phases may be present in the anti-wear layer.

In this way, coated objects can be obtained that combine high hardness, low intrinsic voltage and excellent adhesion to metallic substrates due to the process control according to the invention.

The substrate is in particular a hard metal, a cermet or a tool steel. The hard metal includes, for example, a metal carbide, wherein the metal is selected from the group consisting of tungsten, titanium, tantalum, niobium and mixtures thereof, and a binder, for example a cobalt-based binder.

The coated object is in particular a cutting tool, for example a cutting tool for chip-removing machining.

According to the invention, the target contains a transition metal of the fifth or sixth group of the periodic table (designated as “Ma”). Such transition metals are able to form the Ma₂C phase of high hardness as envisaged in the invention. This is not possible with other metals, such as titanium.

For example, the target contains vanadium, niobium, tungsten or molybdenum. Accordingly, the Ma₂C phase can be a V₂C, Nb₂C, W₂C or Mo₂C phase.

In principle, the type of PVD method is not further restricted, as long as the desired Ma₂C phase can be specifically generated. For example, the anti-wear layer is applied by means of magnetron sputtering or an arc method.

The anti-wear layer is applied in particular by means of magnetron sputtering. Magnetron sputtering enables rapid layer growth when depositing the anti-wear layer while maintaining constant pressure within the reaction chamber.

In particular, the argon flow through the reaction chamber when depositing the anti-wear layer is 200 to 600 mLₙ/min, preferably 300 to 500 mLₙ/min, wherein mL/min here and in the following denotes the volume of the respective gas under standard conditions (273.15 K and 1013.25 hPa) per minute.

The anti-wear layer is preferably applied by means of HIPIMS (high power impulse magnetron sputtering), wherein power pulses are applied to the target and voltage pulses are applied to the substrate, and wherein the power pulses and the voltage pulses are applied with a time delay. Compared to other magnetron sputtering methods, HIPIMS is characterized by further increased power densities and high degrees of ionization of the material removed from the target. By using power pulses, each of the pulses can have a higher maximum power than would be possible with a permanently applied electrical field, since the discharge occurs in a short time interval. The target can cool down between the respective power pulses.

The power pulses are used to remove material from the target placed in the reaction chamber and to release it into the plasma present in the reaction chamber. The voltage pulses applied to a rotary table with the objects or substrates to be coated accelerate the ionized material from the plasma towards the substrate, so that the material is deposited in the form of an anti-wear layer on the substrate placed in front of it.

Accordingly, each power pulse at the target is assigned a voltage pulse at the substrate or substrate holder. The time delay between the power pulse and the voltage pulse refers to the respectively assigned power and voltage pulses. This is also known as a “synchronized pulse”.

The time delay makes it possible to specifically adjust the proportion of metal ions in the plasma in the reaction chamber at the point in time at which the ions are accelerated out of the plasma towards the substrate, and thus to produce the desired composition in the deposited phase. This results in a particularly flexible method design. By way of example, reference is made to the method for coating a substrate using HIPIMS as described in EP 2 761 050 B1.

The time delay is in particular a time delay of 30 to 100 μs, preferably of 40 to 80 μs. A shorter time delay can lead to the increased incorporation of argon ions into the anti-wear layer, which would increase its intrinsic compressive voltage, while a time delay of more than 100 us can lead to a reduction in the quantity of metal ions.

Furthermore, in comparison to other PVD methods, the proportion of argon incorporated into the growing layer is reduced and the proportion of implanted metal ions is increased when the anti-wear layer is deposited using HIPIMS. In this way, the intrinsic voltage of the anti-wear layer is further reduced without having to fear disadvantages in terms of the achievable plastic hardness.

The target power, i.e., the cathode power in the HIPIMS process, is particularly 5 to 12 KW, preferably 6 to 10 kW.

The bias voltage between the target and the substrate is in the range of 50 to 250 V, preferably from 120 to 200 V.

To supply the reaction chamber with the carbon needed to form the Ma₂C phase, an additional graphite cathode can be used to supply carbon to the reaction chamber during the deposition of the anti-wear layer.

The operation of the graphite cathode is synchronized with the target pulses that erode material from the target, so that the desired transition metal to carbon ratio is achieved in the plasma, in turn producing the desired composition of the phase to be deposited on the substrate. In other words, co-sputtering is carried out in this variant.

In particular, the graphite cathode power is 1 to 5 KW. Thus, the graphite cathode power is particularly lower than the target power.

In addition to or as an alternative to the use of a graphite cathode, the reaction chamber can be flushed with a reactive gas containing carbon, such as acetylene, to supply carbon during the deposition of the anti-wear layer.

For example, the flow of reactive gas containing carbon through the reaction chamber when depositing the anti-wear layer is 10 to 100 mLₙ/min, preferably 20 to 50 mLₙ/min.

The carbon-containing reactive gas, for example acetylene, is split in the plasma present in the reaction chamber, wherein the carbon ions necessary to generate the Ma₂C phase are produced. In other words, reactive sputtering is carried out in this variant.

In order to further simplify the design and operation of the reaction chamber, either a graphite cathode is provided or the reaction chamber is flushed with the carbon-containing reactive gas when the anti-wear layer is deposited.

The reaction chamber is heated to a temperature in the range of 100 to 600° C., preferably from 300 to 500° C. At temperatures below 100° C., the layer adhesion of the anti-wear layer to the substrate may be insufficient. A temperature of over 600° C. leads to an increasingly excessive energy requirement and can cause graphite to be precipitated in the anti-wear layer, which would result in a reduction in hardness.

In the reaction chamber, a pressure of 0.1 to 0.5 Pa is set during the deposition of the anti-wear layer, preferably from 0.2 to 0.45 Pa. A pressure of less than 0.1 Pa can lead to insufficient layer growth rates, while a pressure of more than 0.5 Pa can reduce the mean free path length of the ions and thus the pulse input into the growing layer too much.

The target may further include a nitride-forming second transition metal, Mb, for producing a nanocrystalline structure comprising a primary phase and a secondary phase when depositing the anti-wear layer, wherein the primary phase is the Ma₂C phase and the secondary phase is a cubic nitride or carbonitride phase containing the second transition metal, Mb.

The target can contain the first transition metal Ma and the second transition metal Mb in the form of an alloy. For example, the target consists of an alloy of the first transition metal Ma and the second transition metal Mb.

The secondary phase causes a reduction in the crystallite sizes in the primary phase, i.e., the crystallites of the Ma₂C phase, so that the microstructure of the anti-wear layer is refined and growth-related intrinsic voltages can be further reduced. A nanocrystalline structure is understood to mean that the respective crystallites of the structure have a size of 10 nm or less.

In this way, a so-called nanocomposite structure is created in the anti-wear layer, in which nitride and/or carbonitride phases coexist with carbide phases, for example Ma₂C/MbN or Ma₂C/MbCN.

The use of the secondary phase in the anti-wear layer further increases its chemical resistance, which has a particularly favorable effect on the service life of the coated object when machining ferrous substrates.

The second transition metal, molybdenum, is a strong nitride former. Preferably, the second transition metal, Mb, is selected from the group consisting of the transition metals of the fourth group of the Periodic Table (also referred to as the “Titanium Group”), vanadium, chromium, and combinations thereof.

To supply the reaction chamber with the nitrogen needed to build up the secondary phase, the reaction chamber can be flushed with a nitrogen-containing reactive gas, for example with nitrogen, to supply nitrogen during the deposition of the anti-wear layer.

The flow of reactive gas containing nitrogen can be 10 to 100 mLₙ/min, preferably 20 to 50 mLₙ/min.

Whether the Ma₂C phase or the secondary phase is deposited at a given time during the deposition process, or a mixture of the two phases, can be adjusted via the target power, the graphite cathode power, the flow of carbon-containing reactive gas and/or the flow of nitrogen-containing reactive gas.

In one variant, the anti-wear layer is the only coating that is applied to the substrate. This results in a particularly simple coating process that, due to the properties of the specifically generated Ma₂C phase, optionally in combination with the secondary phase, already leads to excellent power characteristics of the coated object.

In another variant, a top layer of MaC, MbN and/or MbCN is applied to the anti-wear layer, wherein Ma denotes the first transition metal Ma and Mb denotes the second transition metal Mb of the target. In other words, a top layer of “conventional” transition metal monocarbide, transition metal nitride or transition metal carbonitride can be applied. In this case, too, the desired composition of the top layer can be achieved by suitably selecting the method parameters, in particular by adjusting the power of the graphite cathode, the flow of reactive gas containing carbon and/or the flow of reactive gas containing nitrogen.

In another variant, a top layer of pure carbon can be applied by switching off the target, i.e., the target made of transition metals. This can further reduce the tendency of the coated object to rub.

The coated object is preferably free of alternating layers. In other words, alternating layers are not applied to the substrate or to the anti-wear layer. Here, alternating layers are understood to be a sequence of at least three layers in which at least two layers chemically different from each other repeat in a regular pattern starting from the substrate. Complicated deposition methods can thus be avoided, while the use of the Ma₂C phase in the anti-wear layer continues to achieve the desired resistance and hardness of the coating.

The anti-wear layer can be applied in a thickness ranging from 1 to 10 μm, preferably from 3 to 6 μm. The required layer thicknesses can be achieved quickly and with comparatively little material. With such layer thicknesses, anti-wear layers with a plastic hardness of at least 30 GPa, preferably at least 35 GPa, can be obtained, which at the same time have a high degree of toughness and thus a low tendency to chip.

Of course, the method according to the invention may include further method steps.

For example, a substrate precursor or the substrate can first be cleaned, in particular with water and/or a solvent.

The substrate precursor can be batched to form several substrates.

In addition, it is possible to perform a fine cleaning of the substrate before introducing it into the reaction chamber, for example by means of plasma etching.

After the anti-wear layer has been deposited, the coated substrate can also be cooled and removed from the reaction chamber.

The object of the invention is further solved by a coated object comprising a substrate and an anti-wear layer applied to the surface of the substrate, wherein the anti-wear layer comprises a Ma₂C phase, wherein Ma is a transition metal of the fifth or sixth group of the Periodic Table, and wherein the content of Ma in the anti-wear layer is at least 60 atomic percent based on the total quantity of transition metals in the anti-wear layer.

The coated object is obtained in particular by means of the method described above. The features and characteristics of the method according to the invention apply analogously to the coated object and vice versa, and reference is made to the above explanations.

The substrate of the coated object is, in particular, a hard metal, cermet or tool steel. The hard metal includes, for example, a metal carbide, wherein the metal is selected from the group consisting of tungsten, titanium, tantalum, niobium and mixtures thereof, and a binder, for example a cobalt-based binder.

The coated object is in particular a cutting tool, for example a cutting tool for chip-removing machining.

The Ma₂C phase is in particular a V₂C—, Nb₂C—, W₂C— or Mo₂C phase.

The anti-wear layer may have a nanocrystalline structure comprising a primary phase and a secondary phase, wherein the primary phase being the Ma₂C phase and the secondary phase being a cubic nitride or carbonitride phase contain a second transition metal Mb. The secondary phase may have a lower hardness than the Ma₂C phase, but a higher toughness.

The second transition metal, Mb, is in particular the same transition metal as previously described in connection with the method according to the invention, and reference is made to the above.

In one variant, the anti-wear layer is the only coating applied to the substrate.

In another variant, a top layer of MaC, MbN and/or MbCN is applied on the anti-wear layer, wherein Ma denotes the same transition metal as in the Ma₂C phase and wherein Mb denotes the same transition metal as in the secondary phase.

The coated object is preferably free of alternating layers. In other words, alternating layers are preferably not applied to the substrate or to the anti-wear layer.

The anti-wear layer can have a thickness in the range of 1 to 10 μm, preferably from 3 to 6 μm.

In particular, the anti-wear layer has a plastic hardness of at least 30 GPa, preferably at least 35 GPa, for example from 35 GPa to 45 GPa. These types of anti-wear layers offer high resistance to mechanical loads, with reduced intrinsic voltage and thus very good layer adhesion on metallic substrates. Such hardness-adhesion combinations are not achievable with coatings that have conventional materials as their main component, for example titanium aluminum nitride (TiAlN) or titanium diboride (TiB₂) as described in the prior art.

Plastic hardness refers to hardness as determined by the force-penetration tester and can be determined in accordance with ISO 14577-1.

In particular, the intrinsic compressive voltage of the anti-wear layer is 4.5 GPa or less, preferably 2.5 GPa or less, for example 2 GPa or less.

The intrinsic compressive voltage of a layer can be determined by measuring the deflection of a flexible, coated sample of known thickness and known modulus of elasticity, wherein the intrinsic compressive voltage can be calculated according to the so-called Stoney equation

$$σ = \frac{{E}_{s} {h}_{s}^{2}}{6 ( 1 - {v}_{s} ) h} \frac{1}{R}$$

where σ denotes the intrinsic compressive voltage, Eₛ the modulus of elasticity of the substrate, hₛ the substrate thickness, h the layer thickness, vₛ the Poisson's ratio of the substrate and R the radius of deflection.

It is also possible to determine the intrinsic compressive voltage using X-ray diffraction. X-ray diffraction can also be used for further characterization of the anti-wear layer. By exciting the sample with Cu Kα radiation and varying the beam angle in the range from 20 to 90 degrees, it is possible to draw conclusions about the presence of crystalline phases, lattice planes and the diameters of coherently scattering areas.

The analysis can be done by fitting the measured diffraction reflexes with a Gaussian function to determine the area, half-width, position of the peak maximum and other characteristics of the reflex.

The half-width of a peak allows the size of the crystallites or the extent of the coherently scattering areas to be determined using the well-known Scherrer formula.

Further features and characteristics arise from the following description of exemplary embodiments, which should not be understood in a restrictive sense, as well as from the drawings.

### BRIEF DESCRIPTION OF THE DRAWINGS

The figures show:

FIG. 1 a first embodiment of a coated object according to the invention,

FIG. 2 a second embodiment of a coated object according to the invention,

FIG. 3 a block diagram of a method according to the invention for producing the coated objects from FIGS. 1 and 2,

FIG. 4 X-ray diffractograms of exemplary anti-wear layers and,

FIG. 5 X-ray diffractograms of further exemplary anti-wear layers.

### DETAILED DESCRIPTION

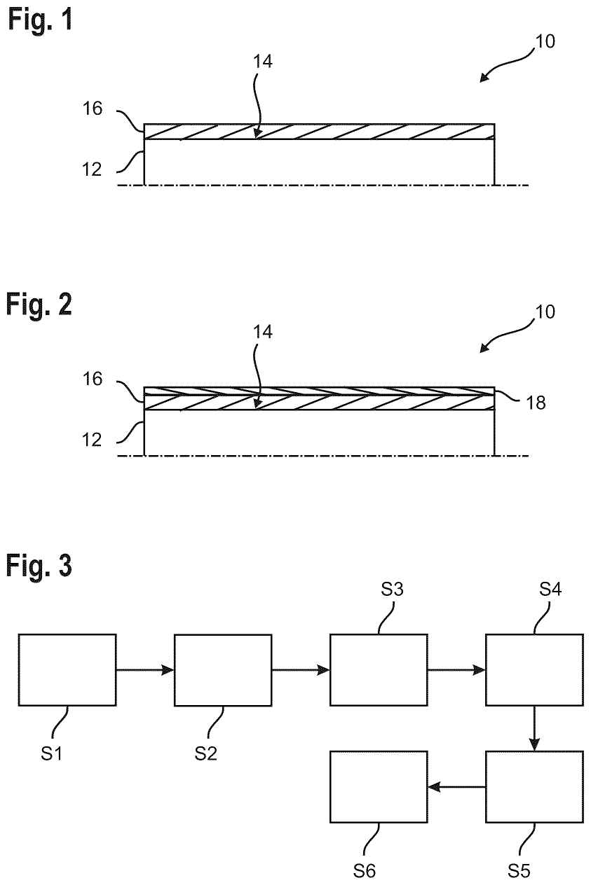

FIG. 1 shows a schematic representation of a first embodiment of the coated object 10 according to the invention, which is in particular a cutting tool, for example a cutting tool for chip-removing machining.

The coated object 10 comprises a substrate 12 and an anti-wear layer 16 applied to a surface 14 corresponding to an upper side of the substrate 12.

The substrate 12 is made of a hard metal, a cermet or a tool steel. The hard metal includes, for example, a metal carbide, wherein the metal is selected from the group consisting of tungsten, titanium, tantalum, niobium and mixtures thereof, and a binder, for example a cobalt-based binder.

The anti-wear layer 16 has a nanocrystalline structure comprising a primary phase and a secondary phase. The primary phase is a Ma₂C phase, wherein Ma is an initial transition metal, which is a transition metal of the fifth or sixth group of the periodic table.

The secondary phase is a cubic nitride or carbonitride phase containing a second transition metal, Mb, selected from the group consisting of transition metals of the fourth group of the Periodic Table, vanadium, chromium and combinations thereof.

The Ma₂C phase is in particular a V₂C—, Nb₂C—, W₂C or Mo₂C phase.

According to the invention, the Ma₂C phase is the main component of the anti-wear layer 16. This means that the proportion of Ma contained in the primary phase in the anti-wear layer 16 is at least 60 atomic percent, based on the total quantity of transition metals in the anti-wear layer 16.

In particular, the ratio of the molar fractions of the nitride- or carbonitride-forming metal Mb to the carbide-forming metal Ma is less than 1:1. For example, the ratio x of the molar fractions of Mb to Ma lies in the range 0.5≤x<1.

In the nanocrystalline structure of the anti-wear layer, the existing crystallites have a size of 10 nm or less. The crystallite size in the primary phase may differ from the crystallite size in the secondary phase. For example, the nitride or carbonitride of the second phase has a higher crystallite size than the Ma₂C of the primary phase.

The anti-wear layer has a hardness of at least 30 GPa, preferably at least 35 GPa, for example from 35 GPa to 45 GPa, and can have a thickness in the range from 1 to 10 μm, preferably from 3 to 6 μm.

As can be seen in FIG. 1, the anti-wear layer 16 is the only layer applied to the substrate 12.

It is also possible to dispense with the use of the secondary phase instead of the nanocrystalline structure with the primary phase and the secondary phase. For example, the anti-wear layer 16 can consist of a Ma₂C phase.

FIG. 2 schematically represents a second embodiment of the object 10 coated according to the invention.

The second embodiment is essentially the same as the first, so only the differences will be discussed below. The same reference numerals indicate the same or functionally identical components and reference is made to the above.

In the second embodiment, an additional top layer 18 is applied to the anti-wear layer 16, wherein the anti-wear layer 16 is arranged between the substrate 12 and the top layer 18.

The top layer 18 is made of a metal carbide (MaC), wherein Ma denotes the same transition metal that is used in the Ma₂C phase of the anti-wear layer 16.

It is also possible that the top layer 18 additionally or alternatively contains a nitride and/or a carbonitride of the second transition metal Mb, wherein Mb denotes the transition metal of the secondary phase.

The top layer 18 is thinner than the anti-wear layer 16.

FIG. 3 shows a block diagram of a method according to the invention for producing the coated object 10 according to the invention.

First, a substrate precursor is provided and subjected to a cleaning step, wherein the cleaning step is carried out in particular with water and/or a solvent (step S1 in FIG. 3).

The substrate precursor is then charged to form several substrates 12 (step S2 in FIG. 3).

Of course, it is also possible to provide and clean the substrate 12 directly, so that the charging step can be omitted.

The substrate 12 is then cleaned, for example by means of plasma etching (step S3 in FIG. 3), after it has been placed in a reaction chamber (step S4 in FIG. 3).

The substrate is then provided with the anti-wear layer 16 and optionally with the top layer 18 by means of PVD (step S5 in FIG. 3), forming the coated object 10.

The anti-wear layer 16, and optionally the top layer 18, are applied to the substrate 12 by means of magnetron sputtering, namely by HIPIMS (high power impulse magnetron sputtering).

The coated object 10 is then cooled and removed from the reaction chamber (step S6 in FIG. 3).

In the following, the method according to the invention and the properties of the coated objects 10 obtained by means of the method according to the invention are further illustrated by means of examples.

### Example 1 (Non-Reactive Process, Pulsed Substrate Voltage)

Tungsten carbide cutting inserts SNGA120408 (6 wt. % Co binder) and steel strips (material C45, dimensions 60×10×0.2 mm) were used as substrates in a CC800 HIPIMS coating system from Cemecon. The reaction chamber was fitted with a segmented target, i.e., a target with an upper half made of tungsten and a lower half made of graphite. Both substrates were provided with an anti-wear layer by means of HIPIMS-PVD, wherein the deposition conditions listed in Table 1 is used. The coated objects were then characterized in terms of their chemical composition using scanning electron microscopy (also referred to as “EDX” for “energy dispersive x-ray analysis”) and in terms of their mechanical properties using a force-indentation tester in accordance with ISO 14577-1 and using bending strips and evaluation of the intrinsic voltage (referred to as “ES”) using the Stoney equation. The layer thickness was approximately 2 μm in all cases.

Table 2 shows the element proportions of tungsten to carbon (each in atomic percent) determined by EDX and other characteristic values of the respective coatings. The variation in the composition of the anti-wear layer is obtained by vertically positioning the substrates within the reaction chamber, resulting in a decreasing metal content from top (sample 1) to bottom (sample 4).

The wear removal, labeled “VA”, was determined by abrasive blasting with corundum powder. In this process, corundum powder is hurled at a pressure of 4 bar for 60 seconds onto the coated test specimens. On a surface that was polished before coating and partially covered during blasting, at least ten individual measurements of the layer thickness are then taken using XRF (X-ray fluorescence analysis). The mean value of these measurements is compared with the initial layer thickness, which is also determined from at least ten individual XRF measurements in the non-irradiated area and set to a value of 100%.

The crystallite size was determined using Peak-Fit and the Scherrer formula, as described above.

TABLE 1
HIPIMS process deposition conditions (non-
reactive process, primary phase only).

| Temperature in ° C. | approx. 500 |
|---|---|
| Pulse frequency in Hz | 2000 |
| Pulse duration in μs | 50 |
| Time delay between power and voltage | 50 |
| pulse (cathode and table pulse) in μs | |
| Target power in kW | 6 |
| Substrate voltage in V | 150 |
| Pressure in Pa | 0.45 |
| Argon flux in mLₙ/min | 500 |

TABLE 2
Properties of coated objects (pulsed substrate
voltage, primary phase only).

| | | Plastic hardness | Intrinsic voltage | |
|---|---|---|---|---|
| Sample | W:C | in GPa | ES in GPa | V_{A} % |
| 1 | 90:10 | 31.2 | 1.5 | −8 |
| 2 | 87:13 | 32.4 | 1.8 | −5 |
| 3 | 79:21 | 34.3 | 1.1 | −3 |
| 4 | 50:50 | 25.8 | 0.5 | −17 |

As can be seen in Table 2, the plastic hardness and abrasion resistance achieved with the composition according to sample 3 is optimal, while both a higher and a lower tungsten content result in a reduction of plastic hardness and wear resistance.

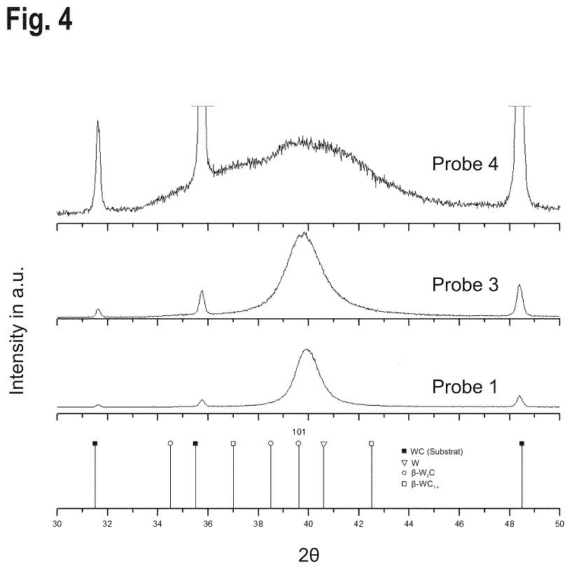

FIG. 4 shows the X-ray diffractograms of samples 1, 3 and 4. It can be seen that with decreasing tungsten content, the intensity of the (101) diffraction reflex of the β-W₂C phase decreases and its width increases. Accordingly, a W:C ratio according to sample 3 results in a W₂C content in the anti-wear layer that enables an optimum in terms of achievable plastic hardness and intrinsic compressive voltage.

By numerically adjusting the respective shape of the (101) diffraction reflex (so-called “fit”), a reflex half-width of 1.6° is obtained. The crystallite size is determined to be approximately 5 nm using the Scherrer formula (ignoring an instrument-related broadening of the reflexes).

The diffraction reflexes recognizable in the X-ray diffractograms, which can be assigned to WC, come from the substrates used in each case.

### Example 2 (Non-Reactive Process, Constant Substrate Voltage)

Analogous to example 1, coated objects were produced in which a non-pulsed or constant substrate voltage of the same level was used instead of a pulsed operation. Table 3 summarizes the properties of the samples obtained, analogous to Table 2.

TABLE 3
Properties of the coated objects (constant substrate voltage).

| | | Plastic hardness | Intrinsic voltage | |
|---|---|---|---|---|
| Sample | W:C | in GPa | ES in GPa | V_{A} % |
| 5 | 91:9 | 27.1 | 0.7 | −7 |
| 6 | 88:12 | 29.0 | 1.1 | −6 |
| 7 | 79:21 | 32.6 | 1.4 | −6 |
| 8 | 51:49 | 24.1 | 0.5 | −15 |

The comparison of samples 1 through 4 from example 1 with the respective analogous samples 5 through 8 from example 2 clearly shows that coated objects produced using HIPIMS have a higher hardness with reduced intrinsic voltage, which leads to a lower wear track depth than is the case with coated objects that were produced with constant substrate voltage with otherwise identical process parameters.

### Example 3 (Reactive Process, Pulsed Substrate Voltage)

To investigate the influence of a nitride-based secondary phase, additional samples were prepared analogously to Example 1, but according to the conditions in Table 4, wherein a segmented target is used in the reaction chamber, which contains tungsten as the first transition metal Ma (upper half) and titanium as the second transition metal Mb (lower half). In addition, the reaction chamber was flushed with acetylene as a carbon-containing reactive gas to supply carbon and with nitrogen as a nitrogen-containing reactive gas to supply nitrogen.

TABLE 4
Deposition conditions for the HIPIMS process
(reactive process, mixed phase).

| Temperature in ° C. | approx. 500 |
|---|---|
| Pulse frequency in Hz | 1000 |
| Pulse duration in μs | 100 |
| Time delay between power and voltage | 50 |
| pulse (cathode and table pulse) in μs | |
| Target power in kW | 6 |
| Substrate voltage in V (HIPIMS) | 180 |
| Pressure in Pa | 0.45 |
| Argon flux in mLₙ/min | 500 |
| Flow of acetylene in mLₙ/min | 20 |
| Nitrogen flow in mLₙ/min | 30 |

Table 5 summarizes the properties of the samples obtained by HIPIMS, analogous to Tables 2 and 3, based on the ratio of the element proportions of tungsten to titanium (each in atomic percent) determined by EDX.

TABLE 5
Properties of the coated objects (pulsed
substrate voltage, mixing phase).

| | | Plastic hardness | Intrinsic voltage | |
|---|---|---|---|---|
| Sample | W:Ti | in GPa | ES in GPa | V_{A} % |
| 9 | 93:7 | 35.4 | 1 | −7 |
| 10 | 89:11 | 36.7 | 1.5 | −3 |
| 11 | 85:15 | 39.4 | 2.5 | 0 |
| 12 | 73:27 | 33.6 | 1.5 | −5 |

On the basis of samples 9 through 12, it is clear that the achievable hardness can be increased over a wide compositional range by the additional nitride or carbonitride-containing secondary phase based on the second transition metal Mb, without having to fear a significant increase in intrinsic voltage. At plastic hardnesses of around 40 GPa (see sample 11), no further wear can be detected under the selected blasting conditions.

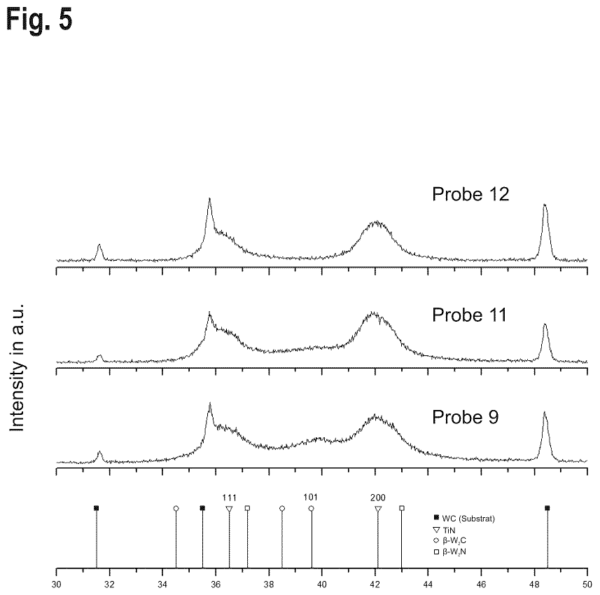

FIG. 5 shows the X-ray diffraction patterns of samples 9, 11 and 12. It can be seen that the TiN phase is dominant in all samples in the X-ray diffraction pattern, wherein the diffraction reflexes of the (111) and (200) lattice planes show a comparable intensity. The reflex of the (101) lattice plane of the W₂C phase is only weakly visible. The crystallite sizes of the phases (calculated according to the Scherrer formula) are in the range of less than 10 nm.

### LIST OF REFERENCE NUMERALS

10 Coated object
12 Substrate
14 Surface
16 Anti-wear layer
18 Top layer

1. A method for producing a coated object, wherein the method comprises the steps of:
providing a substrate in a reaction chamber, and
depositing an anti-wear layer on a surface of the substrate by means of physical vapor deposition, wherein a target is provided in the reaction chamber, which target contains at least a first transition metal Ma, which is a transition metal from the fifth or sixth group of the periodic table, to produce a Ma₂C phase in the anti-wear layer, and wherein the proportion of Ma of the Ma₂C phase in the anti-wear layer is at least 60 atomic percent, relative to the total quantity of transition metals in the anti-wear layer.

2. The method according to claim 1, wherein Ma is selected from the group consisting of vanadium, niobium, tungsten, molybdenum, and combinations thereof.

3. The method according to claim 1, wherein the anti-wear layer (16) is applied by means of magnetron sputtering.

4. The method according to claim 3, wherein the anti-wear layer is applied by means of HIPIMS, wherein the target is supplied with power pulses and the substrate is supplied with voltage pulses, and wherein the power pulses and the voltage pulses are supplied with a time delay.

5. The method according to claim 1, wherein in addition a graphite cathode is provided for supplying carbon in the reaction chamber when depositing the anti-wear layer (16).

6. The method according to claim 1, wherein, for the supply of carbon, the reaction chamber is flushed with a reactive gas containing carbon during the deposition of the anti-wear layer.

7. The method according to claim 1, wherein the reaction chamber is heated to a temperature in the range of 100 to 600° C.

8. The method according to claim 1, wherein a pressure of 0.1 to 0.5 Pa is set in the reaction chamber.

9. The method according to claim 1, wherein the target further comprises a nitride-forming second transition metal Mb to produce a nanocrystalline structure comprising a primary phase and a secondary phase upon deposition of the anti-wear layer, wherein the primary phase is the Ma₂C phase and the secondary phase is a cubic nitride or carbonitride phase comprising the second transition metal Mb.

10. The method according to claim 9, wherein the second transition metal Mb is selected from the group consisting of the transition metals of the fourth group of the periodic table, vanadium, chromium, iron and combinations thereof.

11. The method according to claim 9, wherein, during the deposition of the anti-wear layer, the reaction chamber is flushed with a nitrogen-containing reactive gas to supply nitrogen.

12. The method according to claim 1, wherein the anti-wear layer is the only coating applied to the substrate.

13. The method according to claim 1, wherein a top layer of MaC, MbN and/or MbCN is applied to the anti-wear layer, wherein Ma and Mb denote the first transition metal and the second transition metal of the target, respectively.

14. The method according to claim 1, wherein the anti-wear layer is applied to a thickness in the range from 1 to 10 μm.

15. A coated object comprising a substrate and an anti-wear coating disposed on a surface of the substrate, wherein the anti-wear coating comprises a Ma₂C phase, wherein Ma is a transition metal of the fifth or sixth group of the periodic table, and wherein the proportion of Ma in the anti-wear layer is at least 50 atomic percent, based on the total quantity of transition metals in the anti-wear layer.

16. The coated object according to claim 15, wherein the anti-wear layer has a plastic hardness of at least 30 GPa.

17. The coated object according to claim 15, wherein the intrinsic compressive voltage of the anti-wear layer is 4.5 GPa or less.
